(19) United States
(12) Patent Application Publication
(10) Pub. No.: US 2007/0101214 A1
(43) Pub. Date: May 3, 2007

(54) Self-testing apparatus with controllable environmental stress screening (ESS)

(76) Inventors: Titus D. Stauffer, Austin, TX (US); Walter J. Belmore, Houston, TX (US); Richard E. Pratz, Houston, TX (US); Tracy L. Bollenbaugh, Houston, TX (US); Mahmut Guner, San Jose, CA (US); David Rosenblitt, Mountain, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/261,038

(22) Filed: Oct. 28, 2005

(51) Int. Cl. G01R 31/28

(52) U.S. Cl. 714/724

(57) ABSTRACT

Systems and methods associated with a self-testing module are described. The module may self control an environmental stress screen (ESS) apparatus and a self-test. One exemplary system includes a substitution test apparatus configured to hold a unit under test (UUT) configured with a self-test logic. The substitution test apparatus facilitates operably connecting the UUT to peripheral computer components so that the UUT and the peripheral components form a computing system when operably connected. The system may include an ESS apparatus for selectively and controllably applying an environmental stress to the UUT, a process control logic for controlling the substitution test apparatus, the UUT, the self-test logic, and/or the ESS apparatus.

### BACKGROUND

Environmental stress screening (ESS) has been performed on different types of equipment for many years. Typically, an item like a computer is exposed to environmental stresses that it may encounter to determine whether the unit is “acceptable” for shipping. For example, a computer may be provided with electrical voltages both inside and outside desired ranges to see how the computer responds. Similarly, a computer may be repeatedly heated and/or cooled to see whether solder points lose their integrity. In some cases, a computer may even been supplied with operating voltages at the high and/or low ends of voltage specifications while other types of tests (e.g., memory validations) are performed. This testing has generally been controlled by an external test fixture that applies stresses to a unit under test (UUT).

Conventionally, ESS is used to pass or fail a UUT. If the UUT passes, it is shipped. If the UUT fails, it is not shipped. Passing and failing are typically defined by compliance with a set of pass/fail criteria. By way of illustration, after heating and cooling, certain solder points may break and thus certain electrical paths may no longer be continuous. If continuity is lost, the UUT fails. Similarly, if varying a direct current (DC) voltage in a test range (e.g., 5 volts +/−0.5 volts) causes memory failures then the unit may fail. These pass/fail tests require objective criteria against which observed results can be measured. Thus, pass/fail values for digital tests (e.g., continuity) and analog tests (e.g., voltage range) may be established for a UUT subjected to ESS. However, these pass/fail values have typically been static and have typically been analyzed individually. Furthermore, coordinating timing between internal UUT tests and external ESS apparatus may have been sub-optimal.

### BRIEF DESCRIPTION OF THE DRAWINGS

The accompanying drawings, which are incorporated in and constitute a part of the specification, illustrate various example systems, methods, and other example embodiments of various aspects of the invention. It will be appreciated that the illustrated element boundaries (e.g., boxes, groups of boxes, or other shapes) in the figures represent one example of the boundaries. One of ordinary skill in the art will appreciate that one element may be designed as multiple elements or that multiple elements may be designed as one element. An element shown as an internal component of another element may be implemented as an external component and vice versa. Furthermore, elements may not be drawn to scale.

FIG. 1 illustrates an example self-testing apparatus with controllable ESS.

FIG. 2 illustrates another example self-testing apparatus with controllable ESS.

FIG. 3 illustrates another example self-testing apparatus with controllable ESS.

FIG. 4 illustrates an example method associated with self-testing with controllable ESS.

FIG. 5 illustrates another example method associated with self-testing with controllable ESS.

FIG. 6 illustrates an example application programming interface (API).

FIG. 7 illustrates an example apparatus associated with a self-testing apparatus having controllable ESS.

### DETAILED DESCRIPTION

A self-testing apparatus with controllable environmental stress screening (ESS) is described. Exercising both self-test control and ESS control from a unit under test (UUT) (e.g., motherboard) facilitates acquiring meaningful data that may conventionally have been difficult, if possible, to acquire. For example, a self-testing apparatus with controllable ESS may acquire self-test data before, during, and/or after ESS. The self-test may be precisely controlled to facilitate acquiring data during a particular internal state and/or during a state transition. This precise timing may be achieved when self-test logic and ESS apparatus are self-controlled by the UUT. A real-time operating system on the UUT may also contribute to the precise timing.

Additionally, the self-testing apparatus may allow a UUT to logically “expand” into a complete system or larger system for testing purposes. By way of illustration, a computer motherboard may be the UUT. The motherboard may not be equipped with a disk drive, a network card, and other peripherals. Thus, a test fixture may be supplied. The test fixture may receive the motherboard, operably connect it to certain peripherals, and then allow the UUT to self-test in this logically expanded configuration. Once again, precise timing control can be exercised by the UUT, even while the UUT interacts with other devices in the test fixture. Isolating the UUT from the additional devices even while operably connecting the UUT to the additional devices facilitates a UUT testing itself as a module with its own internal timing control in place. A “module” may be considered to be a discrete component of a larger system that can operate, at least partially, independently from other components in the larger system. A module may connect to and/or cooperate with other components. A module may “enlarge” itself by connecting to other components.

The following includes definitions of selected terms employed herein. The definitions include various examples and/or forms of components that fall within the scope of a term and that may be used for implementation. The examples are not intended to be limiting. Both singular and plural forms of terms may be within the definitions.

“Computer component”, as used herein, refers to a computer-related entity (e.g., hardware, firmware, software, combinations thereof). Computer components may include, for example, a process running on a processor, a processor, an object, an executable, a thread of execution, a program, and a computer. A computer component(s) may reside within a process and/or thread. A computer component may be localized on one computer and/or may be distributed between multiple computers.

“Computer-readable medium”, as used herein, refers to a medium that participates in directly or indirectly providing signals, instructions and/or data that can be read by a computer. A computer-readable medium may take forms, including, but not limited to, non-volatile media (e.g., optical disk, magnetic disk), volatile media (e.g., semiconductor memory, dynamic memory), and transmission media (e.g., coaxial cable, copper wire, fiber optic cable, electromagnetic radiation). Common computer-readable mediums include floppy disks, hard disks, magnetic tapes, CD-ROMs, RAMs, ROMs, carrier waves/pulses, and so on. Signals used to propagate instructions or other software over a network, like the Internet, can be considered a “computer-readable medium.”

“Data store”, as used herein, refers to a physical and/or logical entity that can store data. A data store may be, for example, a database, a table, a file, a list, a queue, a heap, a memory, a register, and so on. A data store may reside in one logical and/or physical entity and/or may be distributed between multiple logical and/or physical entities.

“Logic”, as used herein, includes but is not limited to hardware, firmware, software and/or combinations thereof to perform a function(s) or an action(s), and/or to cause a function or action from another logic, method, and/or system. Logic may include a software controlled microprocessor, discrete logic (e.g., application specific integrated circuit (ASIC)), an analog circuit, a digital circuit, a programmed logic device, a memory device containing instructions, and so on. Logic may include a gate(s), a combinations of gates, other circuit components, and so on. In some examples, logic may be fully embodied as software. Where multiple logical logics are described, it may be possible in some examples to incorporate the multiple logical logics into one physical logic. Similarly, where a single logical logic is described, it may be possible in some examples to distribute that single logical logic between multiple physical logics.

An “operable connection”, or a connection by which entities are “operably connected”, is one in which signals, physical communications, and/or logical communications may be sent and/or received. An operable connection may include a physical interface, an electrical interface, and/or a data interface. An operable connection may include differing combinations of interfaces and/or connections sufficient to allow operable control. For example, two entities can be operably connected to communicate signals to each other directly or through one or more intermediate entities (e.g., processor, operating system, logic, software). Logical and/or physical communication channels can be used to create an operable connection.

“Signal”, as used herein, includes but is not limited to, an electrical signal, an optical signal, an analog signal, a digital signal, data, a computer instruction(s), a processor instruction(s), messages, a bit, a bit stream, or other means that can be received, transmitted and/or detected.

“Software”, as used herein, includes but is not limited to, one or more computer instructions and/or processor instructions that can be read, interpreted, compiled, and/or executed by a computer and/or processor. Software causes a computer, processor, or other electronic device to perform functions, actions and/or behave in a desired manner. Software may be embodied in various forms including routines, algorithms, modules, methods, threads, and/or programs. In different examples software may be embodied in separate applications and/or code from dynamically linked libraries. In different examples, software may be implemented in executable and/or loadable forms including, but not limited to, a stand-alone program, a function call (local and/or remote), a servelet, an applet, instructions stored in a memory, part of an operating system, and so on. In different examples, computer-readable and/or executable instructions may be located in one logic and/or distributed between multiple communicating, cooperating, and/or parallel processing logics and thus may be loaded and/or executed in serial, parallel, massively parallel and other manners.

Suitable software for implementing various components of example systems and methods described herein may be developed using programming languages and tools (e.g., Java, C, C#, C++, C, SQL, APIs, SDKs, assembler). Software, whether an entire system or a component of a system, may be embodied as an article of manufacture and maintained or provided as part of a computer-readable medium. Software may include signals that transmit program code to a recipient over a network or other communication medium. Thus, in one example, a computer-readable medium may be signals that represent software/firmware as it is downloaded from a server (e.g., web server).

“User”, as used herein, includes but is not limited to, one or more persons, software, computers or other devices, or combinations of these.

Some portions of the detailed descriptions that follow are presented in terms of algorithm descriptions and representations of operations on electrical and/or magnetic signals capable of being stored, transferred, combined, compared, and otherwise manipulated in hardware. These algorithmic descriptions and representations are the means used by those skilled in the art to convey the substance of their work to others. An algorithm is here, and generally, conceived to be a sequence of operations that produce a result. The operations may include physical manipulations of physical quantities.

It has proven convenient at times, principally for reasons of common usage, to refer to these electrical and/or magnetic signals as bits, values, elements, symbols, characters, terms, numbers, and so on. These and similar terms are associated with appropriate physical quantities and are merely convenient labels applied to these quantities. Unless specifically stated otherwise, it is appreciated that throughout the description, terms including processing, computing, calculating, determining, displaying, automatically performing an action, and so on, refer to actions and processes of a computer system, logic, processor, or similar electronic device that manipulates and transforms data represented as physical (electric, electronic, magnetic) quantities.

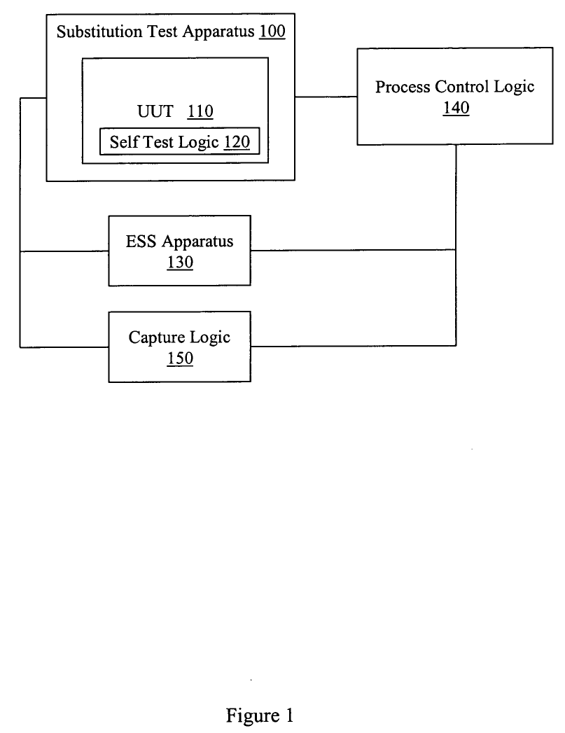

FIG. 1 illustrates a system associated with a self-testing apparatus having controllable ESS. The system includes a substitution test apparatus 100 that is configured to hold a UUT 110. UUT 110 may be, for example, a computer motherboard. UUT 110 may also be, for example, other computing components that can accommodate a programmable logic like an application specific integrated circuit (ASIC). UUT 110 is configured with a self-test logic 120. Self-test logic 120 may be programmed to test various sub-systems (e.g., memory, continuity) on UUT 110 and/or various interactions between UUT 110 and other computer components (e.g., disk, network). Thus, substitution test apparatus 100 may be configured to operably connect UUT 110 to peripheral computer components (e.g., disk, memory, network).

When UUT 110 is operably connected to substitution test apparatus 100 and the peripheral component(s), UUT 110 and the operably connected items may form a larger and/or complete testable system. However, it may still be desirable to test UUT 110 as a module rather than as a larger and/or complete system. Furthermore, it may be desirable to have UUT 110 control its own test environment. This self-control may facilitate timing-sensitive and/or state sensitive data. Thus, UUT 110 may be configured to control both self test logic 120 and substitution test apparatus 100. In one example, substitution test apparatus 100 facilitates operably connecting the motherboard to other components (e.g., disk, memory) that allow the motherboard to operate as a complete computing system. Thus, UUT 110 may temporarily logically expand itself into a larger system while housed in substitution test apparatus 100 but may still retain the ability to self-test itself as a module.

The system may also include an ESS apparatus 130 that is configured to selectively and controllably apply an environmental stress to UUT 110. The environmental stress may be, for example, a vibration, and/or a manipulated direct current (DC) voltage (e.g., margined, spiked). In some examples, the environmental stress may also include heat, cold, moisture (e.g., humidity), airborne particulate contaminants, and so on. While ESS apparatus 130 is illustrated outside substitution test apparatus 100 and outside UUT 110, it is to be appreciated that in some examples either UUT 110 and/or substitution test apparatus 100 may incorporate ESS apparatus 130. For example, UUT 110 may include circuits to margin and/or spike DC voltages on UUT 110. Similarly, substitution test apparatus 100 may include a vibrator for vibrating UUT 110, a heater for heating UUT 110, a piston for jolting UUT 110, and so on.

In one example, ESS apparatus 130 may provide an environmental stress in the form of a manipulated DC voltage. For example, ESS apparatus 130 may provide direct current at different voltages (e.g., +3.3V, +5V, +12V) and may facilitate selectively varying these voltages in different ranges (e.g., −8% to +10%, −5% to +5%). While −8% to +10% is described, it is to be appreciated that in other examples other ranges may be employed. These selectively controllable voltages may be applied to different power rails in a UUT. For example, when UUT 110 is a motherboard, the direct current voltages may be supplied to a +3.3V rail on the UUT, a +5V rail on the UUT, a +3.3V auxiliary rail on the UUT, a +5V auxiliary rail on the UUT, a +12V rail on the UUT, and so on.

The system may also include a process control logic 140 that is configured to control substitution test apparatus 100, UUT 110, self-test logic 120, and/or ESS apparatus 130. While process control logic 140 is illustrated outside UUT 110, in one example, process control logic 140 may be a part of UUT 110. For example, process control logic 140 may be an ASIC on UUT 110. In different examples, process control logic 140 may be removably attached to UUT 110. Therefore, different process control logics may be associated with a UUT. Additionally, process control logic 140 may, in some examples, be user writeable and/or user configurable.

Process control logic 140 places UUT 110 in charge of controlling environmental stresses applied to itself and also in charge of controlling when it will test itself. This self-control facilitates fine-grained precision with respect to when test data is acquired. For example, conventional external control may not be able to coordinate stresses with internal state transitions experienced by a UUT. However, having UUT 110 control both when stresses will be applied and when testing will occur facilitates testing during, at, and/or around internal state transitions. Thus, smaller periods of time may be required to acquire meaningful test data. Therefore, overall test time for a unit may be reduced. Furthermore, subsequent data processing (e.g., error curve fitting) may be enhanced by the improved quality of the underlying test data.

In some examples process control logic 140 may be user configurable. For example, a programming language and/or application programming interface (API) may be provided to facilitate scheduling environmental stresses and self-tests. Additionally, stress and/or test control may be parameterized, which facilitates specifying data to collect from a test. Process control logic 140 may be configured to control, for example, when a self-test logic will start a UUT self-test, when a self-test logic will end a UUT self-test, when an ESS apparatus will start applying an environmental stress to a UUT, when an ESS apparatus will stop applying an environmental stress to a UUT, which peripheral computer component(s) are operably connected to a UUT, and so on. Therefore, process control logic 140 may control, for example, parameters of an environmental stress like a voltage spike applied to UUT 110. For example, process control logic 140 may control a DC power spike environmental stress with respect to spike amplitude, spike frequency, and/or spike duration.

The system may also include a capture logic 150 that is configured to acquire a test data from UUT 110. The test data may include, for example, information concerning communications within UUT 110, communications between UUT 110 and a peripheral component, memory tests performed on UUT 110, processor tests performed on UUT 110, and so on. This data may facilitate identifying whether a UUT has passed or failed a test. Capture logic 150 may be configured to acquire test data at times including, before an environmental stress is applied to UUT 110, while an environmental stress is applied to UUT 110, and after an environmental stress is applied to UUT 110. Thus, capture logic 150 may acquire data concerning state transitions that was conventionally difficult, if possible at all, to acquire.

Data that is captured in isolation during ESS may have some value. However, data captured during ESS that has ESS feedback information associated with it may have a greater value. For example, a self-test may assume that a first environmental stress was applied during the self-test since information about an environmental stress requested by process control logic 140 may be available. However, that environmental stress may not have been provided by ESS apparatus 130. Thus, the captured data may be based on an unwarranted assumption. In one example, the system may therefore include a direct current voltage feedback logic configured to provide a DC voltage feedback data from UUT 110. Thus, rather than capture logic 150 associating a self-test result with a requested environmental stress, capture logic 150 may associate the self-test result with an actual environmental stress (e.g., margined voltage, voltage spike).

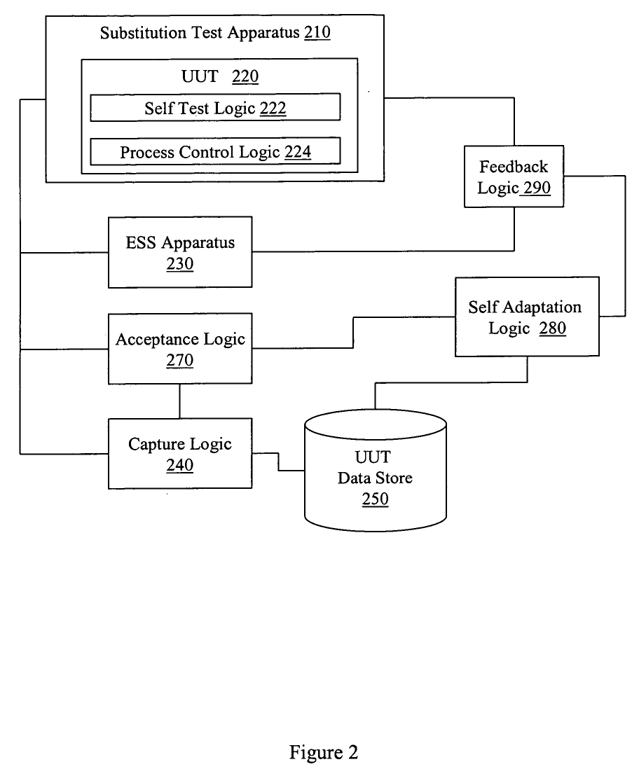

FIG. 2 illustrates a system that facilitates a self-testing apparatus (e.g., computer module) temporarily logically expanding into a larger system while retaining the ability to self-test. The system also facilitates applying environmental stresses to the self-testing apparatus. In this example, both the stresses and the self-testing can be self-controlled by the apparatus (e.g., UUT 220). The system in FIG. 2 has some components that are similar to those illustrated in FIG. 1. For example, the system includes a substitution test apparatus 210 that can hold UUT 220. UUT 220 is illustrated with a self test logic 222 and a process control logic 224 like those described in connection with FIG. 1. The system also includes an ESS apparatus 230 and a capture logic 240 similar to those described in connection with FIG. 1. However, the system illustrated in FIG. 2 includes additional elements.

For example, the system illustrated in FIG. 2 includes a data store 250 that is configured to store test data concerning UUT 220. The test data may include, for example, a digital domain test data and an analog domain test data. The digital domain test data may describe, for example, tests having discrete results (e.g., pass/fail, hi/lo, number of errors). The analog domain test data may describe, for example, tests having analog results (e.g., temperature, voltage level). Additionally, the test data may include a read/write/compare error data, a memory error data, a processor test data, a discontinuity data, a temperature data, and so on. It is to be appreciated that different self test logics may be programmed to acquire different sets of test data.

The system may also include an acceptance logic 270 that is configured to determine whether UUT 220 satisfies a configurable acceptance criteria. The determination may depend, at least in part, on the test data. For example, a unit may fail if the test data indicates that voltage margining created an unacceptable number of memory failures. Similarly, a unit may fail if voltage spiking created an unacceptable temperature response. Unlike conventional systems, the data upon which these determinations is made may be much more precise with respect to being acquired at a desired time, to being acquired when UUT 220 is in a desired state, and/or to being acquired when UUT 220 is transitioning between states. For example, errors that occur during a first state and/or a third state may be uninteresting concerning acceptance criteria while errors occurring during a second state that is a transition state between the first and third state may be interesting. Conventionally, it may have been difficult to control a unit under test and/or test apparatus to create conditions during the second state and/or to acquire data during that second state. Configuring UUT 220 with self-test logic 222 and process control logic 224 may facilitate controlling stress and test timing to acquire data during the relevant/interesting time period.

To facilitate understanding and evaluating temperature responses, in one example UUT 220, substitution test apparatus 210, and/or the system may be configured with an ambient temperature sensor. Thus, temperatures retrieved from UUT 220 may be better understood when compared to the ambient temperature. For example, a first temperature that differs from a first ambient temperature by one hundred degrees may lead to a first conclusion while the same first temperature differing by a hundred degrees from a much higher second ambient temperature may lead to a different conclusion.

The system may also include a self-adaptation logic 280 that is configured to selectively manipulate a portion(s) of the system. The portions manipulated may include, for example, the acceptance criteria, self test logic 222, process control logic 224, and so on. The manipulations may be based, for example, on relationship(s) between members of the test data and feedback data acquired during testing. In one example, self-adaptation logic 280 may manipulate process control logic 224 with respect to attributes including an amount of environmental stress to apply to UUT 220, a type of environmental stress to apply to UUT 220, a duration of an environmental stress to apply to UUT 220, and a combination of environmental stresses to apply to UUT 220. The manipulations may be based, at least in part, on a correlation between element(s) of the test data.

Various components illustrated in FIG. 2 may communicate with other components. In one example, process control logic 224 may communicate with ESS apparatus 230, UUT 220, self-test logic 222, and other components using, for example, an IIC interface, a GPIO interface, and so on. Since the components may communicate, the system may be configured with a feedback logic 290 that is configured to provide a feedback data to process control logic 224. The feedback data may describe, for example, an environmental stress control signal received and an environmental stress achieved in response to that signal. Thus, acceptance and/or manipulation decisions based on environmental stresses may be based on actual stresses rather than desired stresses. In conventional systems, an environmental stress may be programmed to be applied to a UUT, but no feedback may be provided concerning what actual stress was applied. Thus, pass/fail decisions may conventionally be made on uncertain data. Feedback logic 290 facilitates making pass/fail decisions on more certain data.

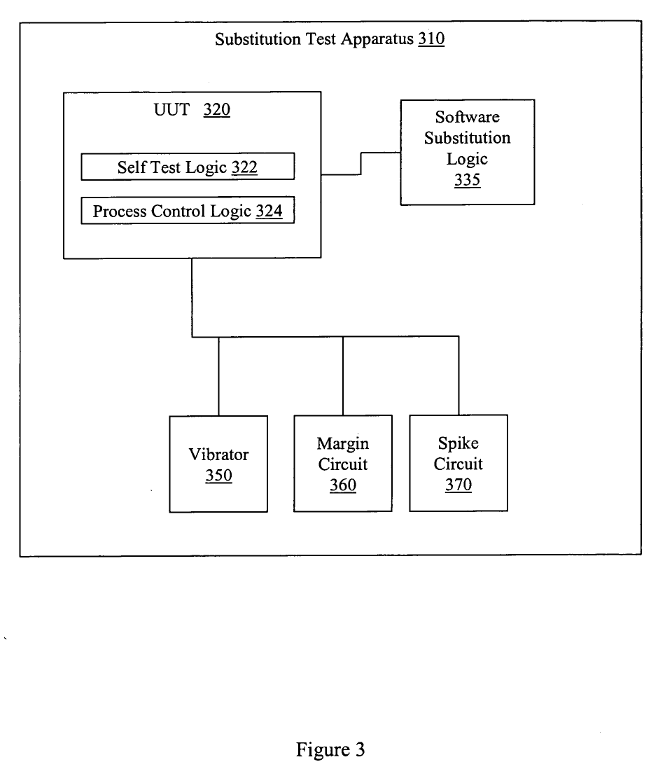

FIG. 3 illustrates a system that facilitates a self-testing apparatus (e.g., computer module) temporarily logically expanding into a larger system while retaining the ability to self-test. The system also facilitates applying environmental stresses to the self-testing apparatus. Both the stresses and the testing can be controlled by the apparatus (e.g., UUT 320). Thus, the system in FIG. 3 has some components similar to those illustrated in FIG. 1. For example, the system includes a substitution test apparatus 310 that can hold UUT 320. UUT 320 is illustrated with a self test logic 322 and a process control logic 324 like those described in connection with FIG. 1. However, the system illustrated in FIG. 3 includes additional elements.

For example, substitution test apparatus 310 includes a software substitution logic 335 that is configured to provide a test software for UUT 320. The test software may be, for example, an application similar to an application that would run in the field on UUT 320, an application designed to produce conditions like those that UUT 320 would experience in the field, and so on.

FIG. 3 illustrates some specific examples of apparatus and/or circuits that may provide environmental stresses to UUT 320. For example, a first environmental stress (e.g., vibration) may be provided by a pneumatically driven rotary vibrator 350 having an off-center center of mass. As vibrator 350 rotates it will produce a vibration due to the off-center center of mass. The vibration may be transmitted through the substitution test apparatus 310 to UUT 320. In another example, vibrator 350 may be in contact with UUT 320 and thus the vibration may be transmitted directly to UUT 320. While a single vibrator 350 is illustrated, it is to be appreciated that a greater number of vibrators may be employed to produce different vibrations in different axes. In one example, vibrator 350 may be controlled by an analog voltage provided by process control logic 324. The analog voltage may be communicated, for example, from process control logic 324 to vibrator 350 using an IIC bus.

Vibrator 350 may be air driven. Thus, vibrator 350 may be associated with an air processing apparatus. The air processing apparatus may provide conditioned high pressure air to drive vibrator 350. Thus, the air processing apparatus may include a source of high pressure air configured to drive the vibrator. The air processing apparatus may also include a control circuit configured to receive the analog voltage provided by process control logic 324 and to establish the pressure of the high pressure air.

Dirty air may negatively impact vibrator 350 and/or UUT 320. Thus, the air processing apparatus may also include a filter that is configured to filter the high pressure air and a dehumidifier that is configured to remove water vapor from the high pressure air. As described above, process control logic 324 may desire a certain vibration and thus may provide a control signal configured to produce the vibration by providing air at a certain pressure to vibrator 350. However, the actual vibration produced may be different than the desired vibration since the actual air pressure may be different than the desired air pressure. Therefore, the air processing apparatus may include a pressure gauge that is configured to provide an air pressure feedback data concerning an actual air pressure provided to vibrator 350.

UUT 320 may also be associated with a voltage margining logic that is configured to control a DC voltage environmental stress. For example, the voltage margining logic may control whether a DC voltage provided to UUT 320 is held constant, whether it is above a tolerance, whether it is lower than a tolerance, how frequently it varies from a tolerance, and so on. The voltage margining logic may include, for example, a voltage margin circuit 360. In one example, voltage margin circuit 360 may include a digital potentiometer that is configured to control a voltage regulator module that is in turn configured to provide the DC voltage environmental stress. In another example, voltage margin circuit 360 may include a zero reference diode(s), an op-amp(s), and an N-channel field effect transistors (FETs).

The system may also include a voltage spiking circuit 370 that is configured to provide the DC power spike environmental stress. In one example, voltage spiking circuit 370 may include multiple (e.g., five) N-channel power FETs that are configured to route a voltage (e.g., +15V) through a power resistor(s) and/or an inductor(s). While N-channel power FETs are described, it is to be appreciated that other electrical and/or electronic components may be employed. Voltage spiking circuit 370 may be configured to produce spikes having certain characteristics. For example, voltage spiking circuit 370 may produce spikes with a pulse width of 1.0 ms and may separate these pulses by 11 ms. Spikes provided to different power rails may have different amplitudes. For example, a spike provided to a 3.3V rail may have a 0.7V amplitude, a spike provided to a 5.0V rail may have a 1.0V amplitude, and a spike provided to a 12V rail may have a 2.0V amplitude.

Example methods may be better appreciated with reference to flow diagrams. While for purposes of simplicity of explanation, the illustrated methods are shown and described as a series of blocks, it is to be appreciated that the methods are not limited by the order of the blocks, as some blocks can occur in different orders and/or concurrently with other blocks from that shown and described. Moreover, less than all the illustrated blocks may be required to implement an example method. In some examples, blocks may be combined, separated into multiple components, may employ additional, not illustrated blocks, and so on. In some examples, blocks may be implemented in logic. In other examples, processing blocks may represent functions and/or actions performed by functionally equivalent circuits (e.g., an analog circuit, a digital signal processor circuit, an ASIC), or other logic device. Blocks may represent executable instructions that cause a computer, processor, and/or logic device to respond, to perform an action(s), to change states, and/or to make decisions. While the figures illustrate various actions occurring in serial, it is to be appreciated that in some examples various actions could occur concurrently, substantially in parallel, and/or at substantially different points in time.

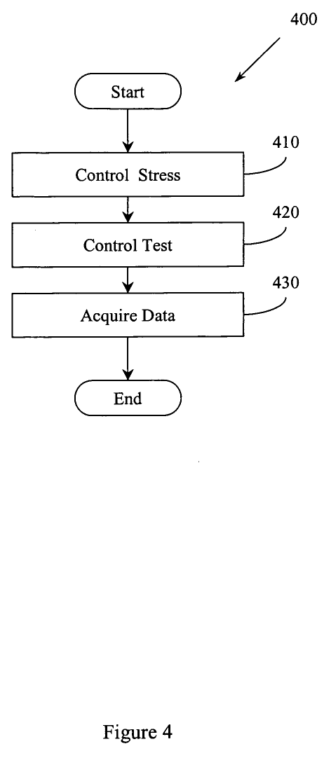

FIG. 4 illustrates a method 400 associated with a self-testing apparatus configured with controllable ESS. Method 400 may include, at 410, controlling an ESS apparatus to selectively apply an environmental stress to a UUT. In one example, the UUT may selectively control the ESS apparatus. The environmental stress may be, for example, a vibration, a margined direct current (DC) voltage, a spiked DC voltage, and so on.

Method 400 may also include, at 420, controlling a self-test logic to selectively initiate a self-test on the UUT. In one example, the UUT may selectively control the self-test logic. Having the UUT exercise both stress and test control facilitates more accurately handling internal timing issues and thus may facilitate acquiring more relevant test data. For example, self-test data may be acquired at times including before, during, and after an internal state transition on the UUT. Conventionally it may have been hit or miss, if possible at all, to reliably acquire such time and/or state transition dependent data.

Method 400 may also include, at 430, acquiring a test data from the UUT. The test data may be acquired, for example, before applying the environmental stress, while applying the environmental stress, and/or after applying the environmental stress. The test data may include, for example, read/write/compare error data, memory error data, processor test data, peripheral communication data, discontinuity data, and so on. In one example, the test data may include an ambient temperature data, and a UUT temperature data. The ambient temperature data may be used to adjust measurements and/or determinations based on the UUT temperature data.

In one example, a method is implemented as processor executable instructions and/or operations stored on a computer-readable medium. Thus, in one example, a computer-readable medium may store processor executable instructions operable to perform a method that includes controlling an ESS apparatus to selectively apply an environmental stress to a UUT, controlling a self-test logic to selectively initiate a self-test on the UUT, and acquiring a test data from the UUT. The UUT may selectively control the ESS apparatus and/or the self-test logic. While the above method is described being stored on a computer-readable medium, it is to be appreciated that other example methods described herein may also be stored on a computer-readable medium.

While FIG. 4 illustrates various actions occurring in serial, it is to be appreciated that various actions illustrated in FIG. 4 could occur substantially in parallel. By way of illustration, a first process could control environmental stresses, a second process could control test timing, and a third process could acquire test data. While three processes are described, it is to be appreciated that a greater and/or lesser number of processes could be employed and that lightweight processes, regular processes, threads, and other approaches could be employed.

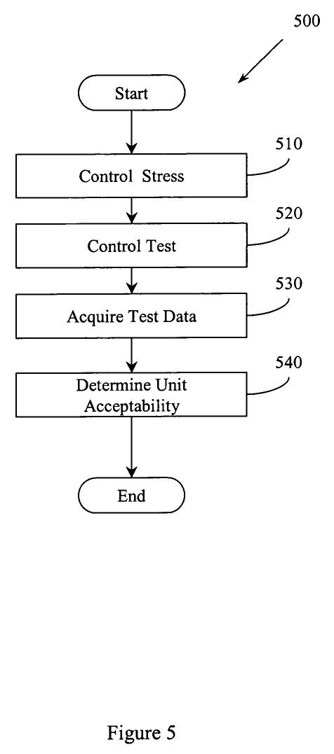

FIG. 5 illustrates a method 500 associated with a self-testing apparatus configured with controllable ESS. Method 500 may include actions 510 through 530 that are similar to actions 410 through 430 (FIG. 4). Method 500 may also include, at 540, determining whether a UUT is an acceptable unit based, at least in part, on the test data and an acceptance data. The acceptance data may be, for example, pass/fail criteria for different tests (e.g., read/write/compare, memory, processor). In one example, the acceptance data may be parameterized and thus may be user and/or machine configurable.

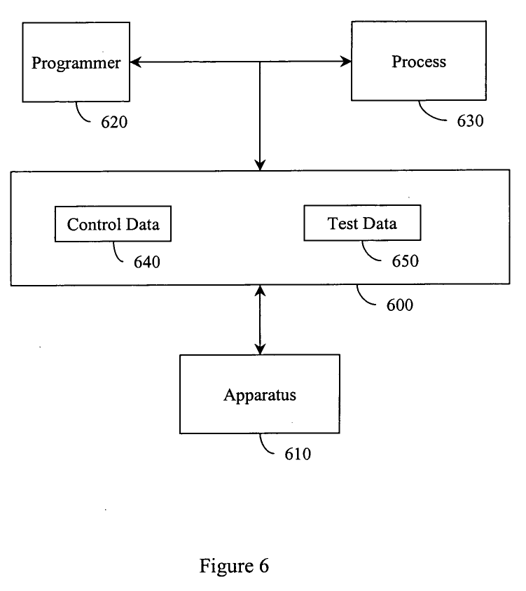

FIG. 6 illustrates an application programming interface (API) 600 that provides access to a self-testing apparatus 610 configured with controllable ESS. API 600 can be employed, for example, by a programmer 620 and/or a process 630 to gain access to processing performed by apparatus 610. For example, programmer 620 can write a program to access apparatus 610 (e.g., invoke its operation, monitor its operation, control its operation) where writing the program is facilitated by the presence of API 600. Rather than programmer 620 having to understand the internals of apparatus 610, programmer 620 merely has to learn the interface to apparatus 610. This facilitates encapsulating the functionality of apparatus 610 while exposing that functionality. API 600 may facilitate providing data values to apparatus 610 and/or may facilitate retrieving data values from apparatus 610. For example, a process 630 that analyzes test data can provide and/or receive test data via API 600.

In one example, an API 600 can be stored on a computer-readable medium. API 600 can be employed by a programmer, computer component, logic, and so on, to gain access to apparatus 610. Interfaces in API 600 can include, but are not limited to, a first interface 640 that communicates a control data, and a second interface 650 that communicates a test data. The control data may include, for example, information concerning when to start a stress, when to end a stress, when to start a test, when to end a test, what stresses to apply, what test(s) to run, what peripherals to isolate from the stress, and so on. In one example, the control data may take the form of instructions associated with a process control scripting language. The test data may include, for example, continuity data, voltage data, temperature data, memory failure data, read/write/compare data, and so on.

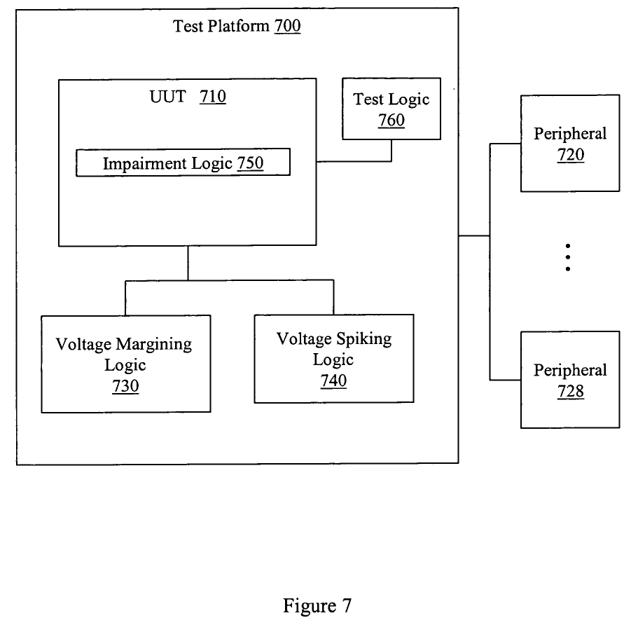

FIG. 7 illustrates a test platform 700 that is configured to hold a UUT 710. Test platform 700 may be configured to selectively vibrate UUT 710. Test platform 700 may also be configured to facilitate operably connecting UUT 710 to peripheral components (e.g., 720 through 728). The peripheral components may include, for example, a processor, a memory stick, a hard drive, a hard drive array controller, a battery backed cache, a SCSI (small computer systems interface) drive, a PCI (peripheral component interconnect) expansion card, a PCI express NIC (network interface controller) card, a video card, a USB (universal serial bus) port, a graphics controller, a mouse, a keyboard, a power supply, a CD (compact disc) drive, a floppy disk drive, and so on. In one example, test platform 700 may be configured to selectively isolate a peripheral component(s) from the environmental stress applied to UUT 710 while in another example test platform 700 may be configured to selectively apply the environmental stress applied to UUT 710 to a peripheral component(s).

Test platform 700 may include a voltage margining logic 730 that is operably connectable to UUT 710. Voltage margining logic 730 may be configured to selectively provide different DC voltages to UUT 710. For example, voltage margining logic 730 may provide three or more individually variable different DC voltages to UUT 710. These different DC voltages may be supplied at different times and with different voltages under the control of impairment logic 750. Conventionally, the timing and/or nature of these voltages would have been controlled by a logic external to UUT 710. Thus, precise timing may not have been achievable.

Test platform 700 may also include a voltage spiking logic 740 that is operably connectable to UUT 710. In the example where voltage margining logic 730 provides three or more individually marginable different DC voltages, voltage spiking logic 740 may be configured to selectively produce a voltage spike on each and/or all of the three or more different DC voltages. Once again, these spikes may be supplied at different times and with different traits (e.g., size, shape) under the control of impairment logic 750. Conventionally, the timing, size, shape, number, duration, and so on of these spikes would also have been controlled by a logic external to UUT 710. This would have further exacerbated attempts to precisely control timing.

Test platform 700 may also include an impairment logic 750 that is configured to selectively control test platform 700, UUT 710, voltage margining logic 730, and/or voltage spiking logic 740. In one example, impairment logic 750 can be a part of UUT 710. For example, impairment logic 750 may be an EPROM (electrically programmable read only memory) on UUT 710. In one example, impairment logic 750 may be configured to control when test platform 700 selectively applies the environmental stress applied to UUT 710 to a peripheral component(s) and/or when test platform 700 selectively isolates a peripheral component(s) from the environmental stress applied to UUT 710. Test platform 700 may also include a test logic 760 configured to acquire a test data from a tested UUT. Test logic 760 may facilitate determining whether UUT 710 is an acceptable unit.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methods for purposes of describing the systems, methods, and so on described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both”. The term “and/or” is used in the same manner, meaning “A or B or both”. When the applicants intend to indicate “only A or B but not both” then the term “only A or B but not both” will be employed. Thus, use of the term “or” herein is not the exclusive use. See, Bryan A. Garner, A Dictionary of Modern Legal Usage 624 (2d. Ed. 1995).

To the extent that the phrase “one or more of, A, B, and C” is employed herein, (e.g., a data store configured to store one or more of, A, B, and C) it is intended to convey the set of possibilities A, B, C, AB, AC, BC, and/or ABC (e.g., the data store may store only A, only B, only C, A&B, A&C, B&C, and/or A&B&C). It is not intended to require one of A, one of B, and one of C. When the applicants intend to indicate “at least one of A, at least one of B, and at least one of C”, then the phrasing “at least one of A, at least one of B, and at least one of C” will be employed.

What is claimed is:

1. A system, comprising:
a substitution test apparatus configured to hold a unit under test (UUT), the UUT being configured with a self-test logic, the substitution test apparatus being configured to operably connect the UUT to one or more peripheral computer components, the UUT and the one or more peripheral components comprising a computing system when operably connected;
an environmental stress screen (ESS) apparatus configured to selectively and controllably apply an environmental stress to the UUT;
a process control logic configured to control one or more of, the substitution test apparatus, the UUT, the self-test logic, and the ESS apparatus, the process control logic being part of the UUT; and
a capture logic configured to acquire a test data from the UUT.

2. The system of claim 1, the process control logic being removably attachable to the UUT, the ESS apparatus being removably attachable to the UUT.

3. The system of claim 1, the one or more peripheral components including one or more of, a processor, a memory stick, a hard drive, a hard drive array controller, a battery backed cache, a SCSI (small computer system interface) drive, a PCI (peripheral component interconnect) expansion card, a PCI express NIC (network interface card), a video card, a USB (universal serial bus) port, a graphics controller, a mouse, a keyboard, a power supply, a compact disc (CD) drive, and a floppy disk drive.

4. The system of claim 1, the process control logic being configured to control one or more of, when the self-test logic will start a UUT self-test, when the self-test logic will end a UUT self-test, when the ESS apparatus will start applying an environmental stress to the UUT, when the ESS apparatus will stop applying an environmental stress to the UUT, and which of the one or more peripheral computer components are operably connected to the UUT.

5. The system of claim 1, the substitution test apparatus being configured to selectively isolate one or more of the peripheral components from the environmental stress applied to the UUT and to selectively subject one or more of the peripheral components to the environmental stress applied to the UUT.

6. The system of claim 1, the environmental stress being associated with one or more of, vibration, direct current (DC) voltage, temperature, humidity, and airborne particulate contaminants.

7. The system of claim 1, the substitution test apparatus including a software substitution logic configured to provide test software for the UUT.

8. The system of claim 1, the capture logic being configured to acquire the test data at one or more of, before an environmental stress is applied to the UUT, while an environmental stress is applied to the UUT, and after an environmental stress is applied to the UUT.

9. The system of claim 1, including:
a data store configured to store the test data; and
an acceptance logic configured to determine whether the UUT satisfies a configurable acceptance criteria based, at least in part, on the test data,
the test data including one or more of, a digital domain test data, an analog domain test data, a UUT identifier, a read/write/compare error data, a memory error data, a processor test data, a discontinuity data, and a temperature data.

10. The system of claim 1, the process control logic being configured to communicate with one or more of, the ESS apparatus, the UUT, and the self-test logic using one or more of, an IIC interface, and a GPIO interface.

11. The system of claim 10, the self-adaptation logic being configured to manipulate the process control logic with respect to one or more of, an amount of an environmental stress to be applied to the UUT, a type of an environmental stress to be applied to the UUT, a duration of an environmental stress to be applied to the UUT, and a combination of environmental stresses to be applied to the UUT, based, at least in part, on a correlation between one or more elements of the test data.

12. The system of claim 1, a vibration environmental stress being provided by a pneumatically driven vibrator having an off-center center of mass, the vibrator being controlled by an analog voltage provided by the process control logic.

13. The system of claim 12, including an air processing apparatus comprising:
a source of high pressure air configured to drive the vibrator;
a control circuit configured to receive the analog voltage provided by the process control logic and to establish the pressure of the high pressure air;
a filter configured to filter the high pressure air;
a dehumidifier configured to remove water vapor from the high pressure air; and
a pressure gauge configured to provide an air pressure feedback data concerning an actual air pressure provided to the vibrator.

14. The system of claim 1, a DC voltage environmental stress being provided by the ESS apparatus.

15. The system of claim 14, including a direct current voltage feedback logic configured to provide a direct current voltage feedback data from the UUT.

16. The system of claim 1, including a voltage margining logic configured to control DC voltage environmental stress, the voltage margining logic comprising:
a digital potentiometer configured to control a voltage regulator module configured to provide the DC voltage environmental stress;
one or more zero reference diodes;
one or more op-amps; and
one or more N-channel field effect transistors (FETs), the voltage margining logic being configured to provide the DC voltage environmental stress.

17. The system of claim 1, a DC power spike environmental stress being controlled by the process control logic, the DC power spike environmental stress being controllable with respect to one or more of, spike amplitude, spike frequency, and spike duration.

18. The system of claim 17, including a voltage spiking circuit configured to provide the DC power spike environmental stress, the voltage spiking circuit comprising five or more N-channel power field effect transistors (FETs) configured to route +15V through one or more power resistors and one or more inductors.

19. The system of claim 1, the system being configured with a feedback logic configured to provide a feedback data to the process control logic, the feedback data being configured to describe an environmental stress control signal received and an environmental stress achieved.

20. A computer motherboard, comprising:
a self-test logic configured to test one or more sub-systems on the motherboard;
an environmental stress logic configured to control one or more environmental stresses that can be applied to the computer motherboard; and
a process control logic configured to control the self-test logic and the environmental stress logic,
the sub-systems including one or more of, a memory, a processor, an electrical path, and an interface with a peripheral, the environmental stresses including one or more of, vibration, DC voltage level, DC voltage spikes,
the process control logic being configured to collectively control one or more environmental stresses applied to the UUT, the computer motherboard being configured to logically self-expand when operably connected to a test fixture.

21. A system, comprising:
means for logically expanding a unit under test (UUT) from a module to a system;
means for controlling an environmental stress applied to the UUT;
means for controlling a self-test performed by the UUT; and
means for acquiring a test data from the UUT;
the means for controlling the environmental stress being a part of the UUT, the means for controlling the self-test being a part of the UUT, and the means for acquiring the test data being a part of the UUT.

22. A set of application programming interfaces embodied on a computer-readable medium for execution by a computer component in conjunction with a self-testing apparatus having controllable environmental stress screening (ESS), comprising:
a first interface for communicating a control data; and
a second interface for communicating a test data.

23. An apparatus, comprising:
a test platform component configured to hold a unit under test (UUT), the test platform being configured to selectively vibrate the UUT, the test platform being configured to facilitate operably connecting the UUT to one or more peripheral components;
a voltage margining logic operably connectable to the UUT, the voltage margining logic being configured to selectively provide three or more different direct current (DC) voltages to the UUT, each of the three or more different DC voltages being selectively marginable;
a voltage spiking logic operably connectable to the UUT, the voltage spiking logic being configured to selectively produce a voltage spike on one or more of the three or more different DC voltages;
an impairment logic configured to selectively control one or more of, the test platform, the UUT, the voltage margining logic, and the voltage spiking logic; and
a test logic configured to acquire a test data from a tested UUT.

24. A method, comprising:
controlling an ESS apparatus to selectively apply an environmental stress to a UUT;
controlling a self-test logic to selectively initiate a self-test on the UUT; and
acquiring a test data from the UUT at one or more of, before applying the environmental stress to the UUT, while applying the environmental stress to the UUT, and after applying the environmental stress to the UUT,
the method being configured to coordinate controlling the ESS apparatus, the self-test logic, and the test data acquisition down to a state transition granularity.

25. The method of claim 24, including determining whether the UUT is an acceptable unit based, at least in part, on the test data and an acceptance criteria.
